(19) United States
(12) Patent Application Publication
(10) Pub. No.: US 2005/0029661 A1
(43) Pub. Date: Feb. 10, 2005

(54) Integrated circuit and associated test method

(75) Inventors: Michel Vallet, Vaulnaveys Le Haut (FR); Sylvain Kritter, Corenc (FR)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignee: STMICROELECTRONICS SA, MONTROUGE (FR)

(21) Appl. No.: 10/839,761

(22) Filed: May 5, 2004

(30) Foreign Application Priority Data
May 5, 2003 (FR) 03 05434

(51) Int. Cl. H01L 29/40; G01R 31/26

(52) U.S. Cl. 257/758; 438/17

(57) ABSTRACT

An integrated circuit is provided that includes an active region and at least one interconnect part. The interconnect part is located above the active region, and includes a plurality of metallization levels and at least one test pad. The test pad is located in one of the metallization levels that is beneath a top one of the metallization levels. In a preferred embodiment, the test pad is located beneath supply lines. Also provided is a method for testing such an integrated circuit.

### CROSS-REFERENCE TO RELATED APPLICATIONS

This application is based upon and claims priority from prior French Patent Application No. 03-05434, filed May 5, 2003, the entire disclosure of which is herein incorporated by reference.

### BACKGROUND OF THE INVENTION

1. Field of the Invention

The present invention relates to the testing of integrated circuits by electron beam scanning, and more particularly to test pads designed to give access to buried metallizations in order to measure the potential thereof using an electron beam.

2. Description of Related Art

FIG. 1 illustrates the principle of electron beam scan measurement. A surface is bombarded with a beam of primary electrons e⁻^{p}, the energy of which may vary from a few hundred eV to a few tens of keV. The surface then re-emits several types of electrons, namely Auger electrons, backscattered electrons and secondary electrons. In electron beam scan tests, the re-emitted secondary electrons e⁻ₛ, the energy of which does not exceed 50 eV, are picked up. The energy of the secondary electrons varies with the potential V of the surface at the point of impact of the primary electron beam.

This principle is used in tools for testing integrated circuits. First, it allows an enlarged image of the surface of a chip to be obtained by scanning this surface with the electron beam. It also makes it possible to measure the change in the potentials at chosen points on the chip by regularly deflecting the electron beam so that it strikes these points. Thus, the change in the potentials is sampled on surface metallizations or on surface test pads connected to buried metallizations.

A conventional test pad is a metal pad, which is generally square, formed in the final metallization level of the integrated circuit in order to allow the potential of a metallization of the same level or of a lower level to be measured. To connect a metallization of a lower level to the test pads, a connecting pad is provided for each intermediate metallization level. The metallization to be tested, where appropriate the intermediate connecting pads, and the test pad are electrically interconnected by vias. The test pad is generally surrounded by other metallizations of various levels.

An integrated circuit is normally covered with a protective insulating coating generally formed from a layer of silicon oxide and a passivation layer. This insulating coating impedes direct measurement of the potential of surface metallizations using an electron beam.

To be able to test integrated circuits produced in recent technologies, the etching width of which is extremely small, for example around 0.12 μm or less, with an electron beam, the insulating coating is removed in order to bare the metallizations of the final level. A direct measurement of the potential, not influenced by the potentials of the surrounding constructions, may thus be performed.

French Patent No. 2 771 853 discloses an integrated circuit test pad that is produced in a surface metallization layer covered with an insulating coating. The pad is surrounded by a first metal ring produced in the surface metallization layer and by a second metal ring produced in a lower metallization layer. The first and second rings are electrically interconnected by at least one via and placed at a set potential. This structure allows measurement of the variations in potential of the surface metallizations by the capacitive effect. This is because the variations in potential of the surface metallizations cause, by capacitive coupling, similar but attenuated potential variations on the external surface of the insulating coating. These attenuated variations are measured by the electron beam test system.

However, such a test pad occupies a large area with several metallization levels. The last metallization level is generally occupied by relatively wide supply lines, for example around 30 μm in width. A pad may be in the form of a square having sides of 2 μm. The placing of the pad in the supply lines results in the formation of holes or notches within the supply lines, the pad having to be surrounded over a certain distance by dielectric material so as to isolate the supply lines. This leads to degradation of the quality of the supply lines by an increase in their resistance and their parasitic capacitance.

### SUMMARY OF THE INVENTION

In view of these drawbacks, it is an object of the present invention to overcome these drawbacks and to provide test pads whose deleterious influence on the supply lines in normal operation is reduced.

Another object of the present invention is to provide an integrated circuit in which the supply lines can be placed independently of the test pads.

A further object of the present invention is to provide test pads that are easily accessible, that are precisely placed and that have a low parasitic capacitance.

One embodiment of the present invention provides an integrated circuit that includes an active region and at least one interconnect part. The interconnect part is located above the active region, and includes a plurality of metallization levels and at least one test pad. The test pad is located in one of the metallization levels that is beneath a top one of the metallization levels. In a preferred embodiment, the test pad is located beneath supply lines.

Another embodiment of the present invention provides a method for testing an integrated circuit. According to the method, there is provided an integrated circuit that includes a plurality of metallization levels and a test pad located in one of the metallization levels that is beneath a top one of the metallization levels. Layers of the integrated circuit that are located above the test pad are locally etched so as to expose an upper surface of the test pad, in order to allow an electrical measurement to be carried out on the test pad. The layers that are locally etched include the top metallization level. In one preferred method, an electrical voltage of the test pad is measured by electron beam scanning.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 illustrates the measurement of a potential by an electron beam;

FIG. 2 is a sectional view of a circuit according to a first embodiment of the present invention;

FIG. 3 is a sectional view of the circuit of FIG. 2 during a test;

FIG. 4 is a sectional view of a circuit according to a second embodiment of the present invention;

FIG. 5 is a sectional view of a circuit according to a third embodiment of the present invention; and

FIG. 6 is a sectional view of a circuit according to a fourth embodiment of the present invention.

### DETAILED DESCRIPTION OF PREFERRED EMBODIMENTS

Preferred embodiments of the present invention will be described in detail hereinbelow with reference to the attached drawings.

Preferred embodiments of the present invention provide an integrated circuit that includes at least one interconnect part provided with a plurality of metallization levels and at least one test pad. The test pad is placed in a metallization level located beneath the top metallization level. Thus, the supply lines may be placed independently of the test pads. Should the test require it, a hole may be drilled in the supply line in order to reach the test pad.

Preferably, the test pad is placed beneath supply lines. In one embodiment of the present invention, the test pad is placed beneath the supply metallization levels. In another embodiment, the test pad is placed in the first supply metallization level. By convention, the “first” metallization level is considered as the one closest to the active parts of the integrated circuit, whereas the “final” metallization level is the one furthest away therefrom. Thus, the “first supply metallization level” is the supply metallization level that is closest to the active parts of the integrated circuit.

In one embodiment of the present invention, the test paid is placed above the signal interconnect metallization levels. In another embodiment, the test pad is placed in the first signal interconnect metallization level.

The test pad is preferably covered by at least one insulating layer, and the test pad is preferably covered by at least two metallization levels. In one embodiment of the present invention, the test pad has dimensions of between 1×1 and 3×3 μm.

The present invention also provides methods for testing an integrated circuit that includes a test pad placed in a metallization level located beneath the top metallization level. According to one preferred embodiment, the upper surface of the pad is exposed by localized etching of the layers placed above the pad in order to allow an electrical measurement to be carried out on the pad. The localized etching may reach a supply line. In one embodiment, the electrical measurement is carried out by electron beam scanning, and the hole is drilled by a focused ion Beam (FIB).

Thus, preferred embodiment of the present invention provide the benefit of test pads that are easily accessible, that are particularly precisely placed and that have a low parasitic capacitance.

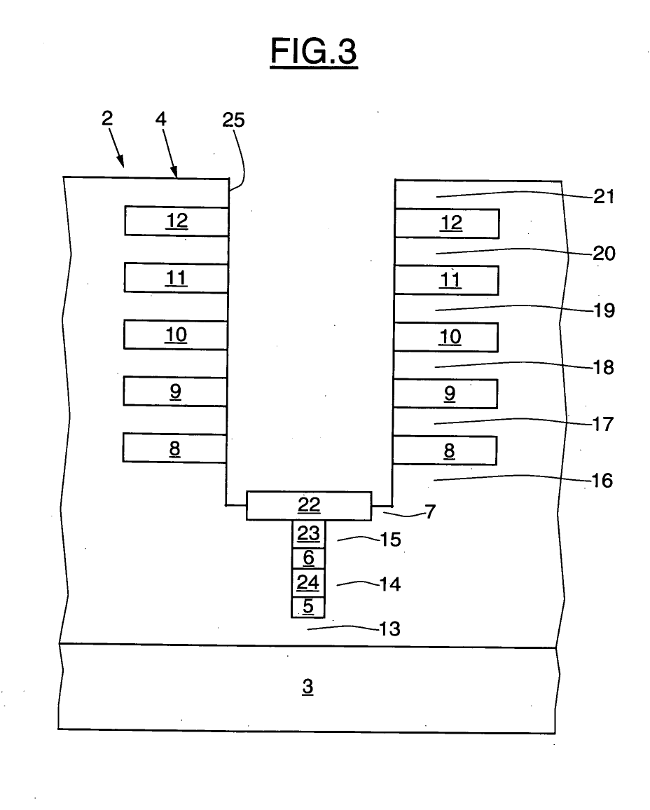

Exemplary embodiments of the present invention will now be described in detail with reference to FIGS. 2-6. FIGS. 2 and 3 show an integrated circuit according to a first embodiment of the present invention. As shown, the integrated circuit 2 includes an active region 3 and an interconnect part 4 that is placed on (or above) the active region 3. The interconnect part 4 includes a plurality of metallization levels, in particular eight levels 5 to 12 in this embodiment, separated by dielectric layers 13 to 21. The dielectric layer 13 is placed between the active region 3 and the first metallization layer 5 and the dielectric layer 21 is placed above the last metallization level 12.

The metallization levels 5 and 6 are intended for signal interconnection and comprise narrow conducting lines separated by dielectric material. The metallization levels 8 to 12 are intended for supplying electrical power and comprise broad conducting lines separated by dielectric material. The metallization level 7, which is placed between those levels intended for interconnection and those levels intended for supply, often comprises a low density of lines, generally a few interconnect lines, with a view to supplementing the signal interconnect lines of the lower metallization levels 5 and 6.

A pad 22, for example of square shape with sides of between 1 and 3 μm and preferably around 2 μm, is formed in the metallization level 7. The width of the pad 22 is therefore substantially greater than that of a signal interconnect line of the lower metallization levels 5 and 6, which may be around 0.09 or 0.12 μm, and substantially less than the width of the supply lines of the upper metallization levels 8 to 12, which may be around several tens of microns, for example 30 μm.

The pad 22 is connected by vias 23 and 24 to the metallization level 6 and the metallization level 5. Provided in the metallization level 6 is a point-like metallization forming a connecting pad for electrical interconnection between the vias 23 and 24. The pad 22 is therefore at the same potential as the metallized line of the metallization level 5 to which it is connected. The pad 22, being placed at a different metallization level from those devoted to the supply lines, in no way interferes with the arrangement of the supply lines. Similarly, by being placed at a metallization level of relatively low density in terms of signal interconnect lines, the pad 22 hardly interferes with the signal supply lines.

The number of types of metallization levels described above are only meant to be illustrative. In different embodiments the number of metallization levels may vary considerably from one circuit to another, as well as whether these levels are devoted to supply or devoted to signal interconnection.

When it is desired to test the integrated circuit by measuring the voltage present on the pad 22, which voltage is equal to the voltage present on the metallized lines of the metallization level 5 to which the pad 22 is connected, a hole 25 is cut out in the interconnect part 4 in order to reach the pad 22, as shown in FIG. 3. The hole passes through the dielectric layers 16 to 21 and the metallization levels 8 to 12 placed above the pads.

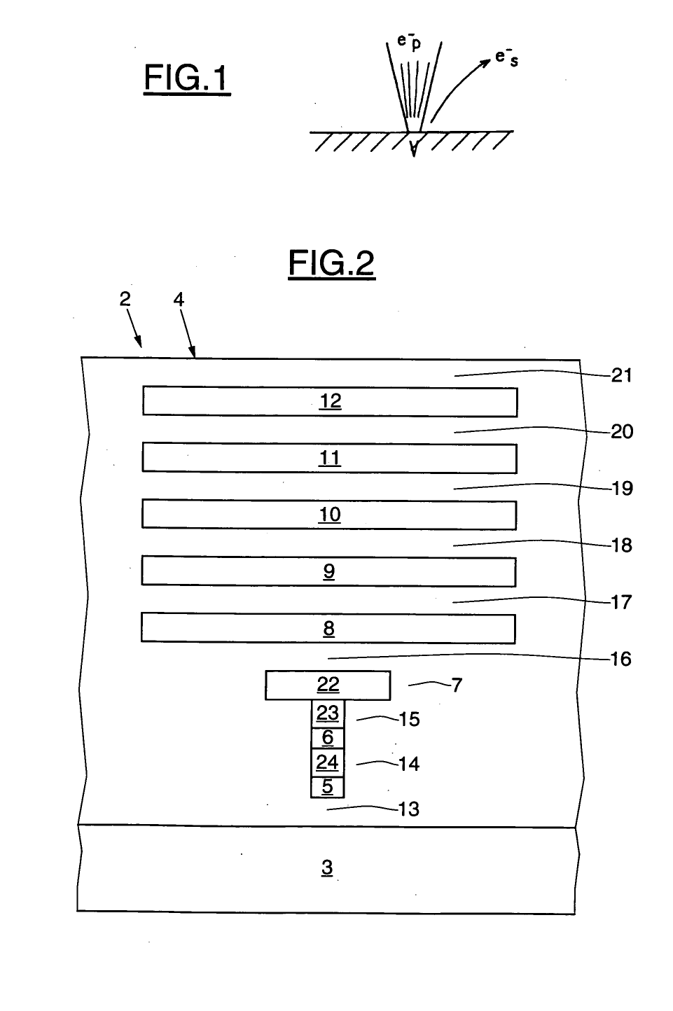

In this embodiment, the hole 25 is formed by a machine capable of precise drilling, while maintaining the electrical isolation between the various metallization levels 8 to 12. For example, the focused ion beam technique is very suitable for such deep narrow holes. The depth of the hole corresponds to several metallization levels, in order to be able to reach the first interconnect level. The width of the hole is compatible with the 0.09 or 0.12 μm signal interconnect lines. Thus, the upper surface of the test pad 22, which can be tested by electron beam scanning as illustrated in FIG. 1, is exposed.

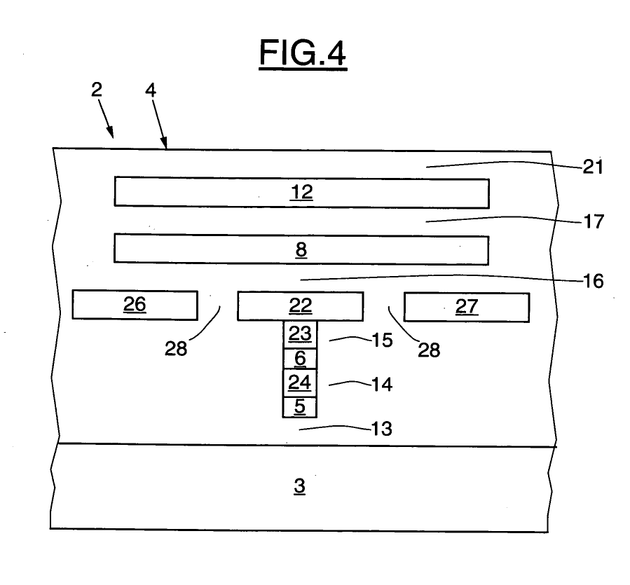

FIG. 4 shows an integrated circuit according to a second embodiment of the present invention. In the embodiment illustrated in FIG. 4, the interconnect part 4 comprises two metallization levels 8 and 12 intended for supply, with the metallization level 12 being the upper level furthest away from the active region 3. The metallization level 7, in which the test pad 22 is formed, also comprises supply lines 26 and 27 that are isolated from the test pad 22 by dielectric material 28. The metallization level 7 therefore comprises both at least one test pad 22 and at least one supply line 26.

This embodiment is advantageous if it is desired not to have signal interconnect lines at the metallization level 7 in which the test pad is provided and, in contrast, when it is desired to have supply lines therein for the purpose, where appropriate, of reducing the total number of metallization levels, which proves to be particularly economical.

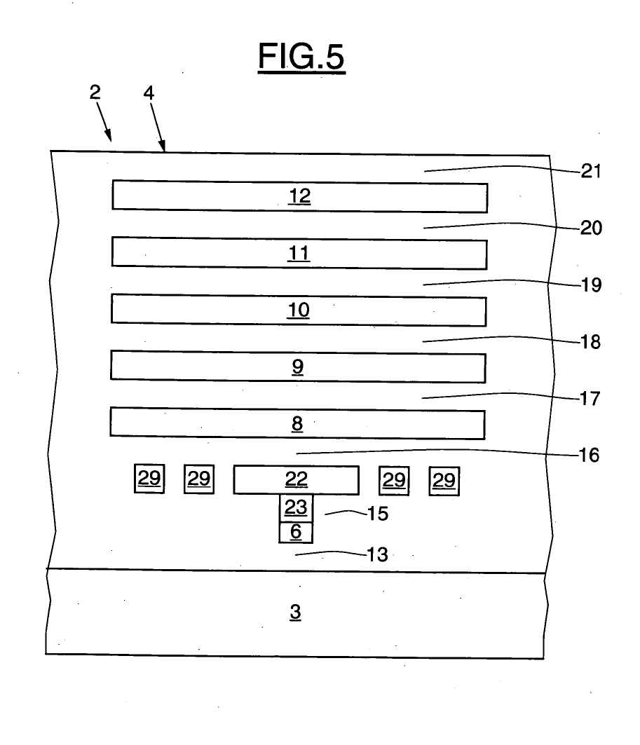

FIG. 5 shows an integrated circuit according to a third embodiment of the present invention. In the embodiment illustrated in FIG. 5, the interconnect part 4 comprises five metallization levels 8 to 12 intended for the supply lines and one metallization level 6 intended for the signal interconnect lines, with this being the metallization level closest to the active region 3. The metallization level 7 comprises, apart from the test pad 22, a plurality of signal interconnect lines 29 of width similar to the signal interconnect lines of the metallization level 6 and isolated from one another and from the test pad 22 by a dielectric material 28.

Preferably, a large width of dielectric material 28 is provided around the test pad 22 so as to prevent the cutting of the hole 25 during a test from damaging the signal interconnect lines 29.

This embodiment is particularly well suited to the case of an integrated circuit in which it is necessary to provide a last metallization level equipped with few signal interconnect lines, leaving the surface available for the formation of the test pad 22. Here again, such an arrangement makes it possible, in certain cases, to reduce the number of metallization levels and therefore to reduce the fabrication cost of the integrated circuit.

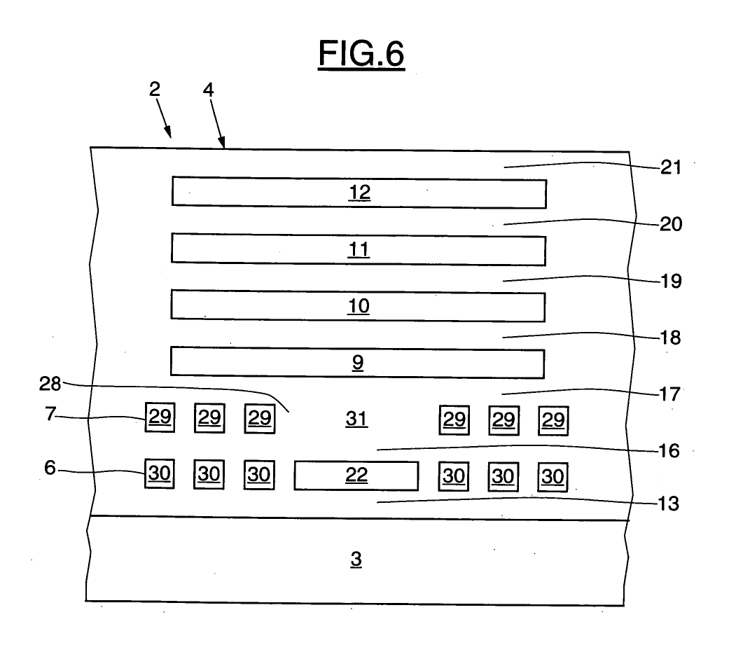

FIG. 6 shows an integrated circuit according to a fourth embodiment of the present invention. The embodiment illustrated in FIG. 6 is similar to the previous one, except that the test pad 22 is placed at the metallization level 6 close to the active region 3, and the metallization level 7, also intended for the signal interconnect lines 29, includes an exposed space 31 that is filled with a dielectric material 28 and located above the test pad 22 so as to allow access to the test pad 22 during the cutting of the hole 25 without damaging the signal interconnect lines 29 of the metallization level 7.

Accordingly, preferred embodiments of the present invention allow contactless measurement on small metal areas forming test pads using an electron beam tester, independent of the arrangement of the supply lines provided in the upper metallization levels. The arrangement of the test pad, or more generally a plurality of test pads, beneath at least one metallization level intended for the supply therefore offers many advantages. For example, the test pad or pads can be placed in the first metallization level intended for the supply lines, in the last metallization level intended for the signal interconnect lines or in an even lower metallization level.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

1. An integrated circuit comprising:
an active region;
at least one interconnect part including a plurality of metallization levels and at least one test pad, the at least one interconnect part being located above the active region,
wherein the at least one test pad is located in one of the metallization levels that is beneath a top one of the metallization levels.

2. The integrated circuit according to claim 1, wherein the test pad is located beneath supply lines.

3. The integrated circuit according to claim 1, wherein the plurality of metallization levels include supply metallization levels, and the test pad is located beneath the supply metallization levels.

4. The integrated circuit according to claim 3, wherein the plurality of metallization levels include signal interconnect metallization levels, and the test pad is located above the signal interconnect metallization levels.

5. The integrated circuit according to claim 3, wherein the plurality of metallization levels include signal interconnect metallization levels, and the test pad is located in a first of the signal interconnect metallization levels.

6. The integrated circuit according to claim 3, further comprising at least one insulating layer that covers the test pad.

7. The integrated circuit according to claim 3, wherein the test pad is covered by at least two of the metallization levels.

8. The integrated circuit according to claim 1, wherein the plurality of metallization levels include supply metallization levels, and the test pad is located in a first of the supply metallization levels.

9. The integrated circuit according to claim 1, wherein the plurality of metallization levels include signal interconnect metallization levels, and the test pad is located above the signal interconnect metallization levels.

10. The integrated circuit according to claim 9, wherein the plurality of metallization levels include supply metallization levels, and the test pad is located in a first of the supply metallization levels.

11. The integrated circuit according to claim 1, wherein the plurality of metallization levels include signal interconnect metallization levels, and the test pad is located in a first of the signal interconnect metallization levels.

12. The integrated circuit according to claim 1, further comprising at least one insulating layer that covers the test pad.

13. The integrated circuit according to claim 1, wherein the test pad is covered by at least two of the metallization levels.

14. The integrated circuit according to claim 1, wherein the test pad has dimensions of between about 1×1 and 3×3 μm.

15. A method for testing an integrated circuit, said method comprising the steps of:
providing an integrated circuit that includes a plurality of metallization levels and a test pad located in one of the metallization levels that is beneath a top one of the metallization levels; and
locally etching layers of the integrated circuit that are located above the test pad so as to expose an upper surface of the test pad, in order to allow an electrical measurement to be carried out on the test pad, the layers that are locally etched including the top metallization level.

16. The method according to claim 15, further comprising the step of measuring an electrical voltage of the test pad by electron beam scanning.

17. The method according to claim 15, wherein the etching step includes the sub-step of using a focused ion beam to perform the localized etching.
